(19) United States
(12) Patent Application Publication
(10) Pub. No.: US 2014/0291670 A1
(43) Pub. Date: Oct. 2, 2014

(54) IMAGE PICKUP DEVICE AND IMAGE PICKUP DISPLAY SYSTEM

(71) Applicant: Sony Corporation, Tokyo (JP)

(72) Inventors: Yasuhiro Yamada, Kanagawa (JP); Makoto Takatoku, Kanagawa (JP); Makoto Hashimoto, Kanagawa (JP); Yasuhito Kuwahara, Aichi (JP)

(73) Assignee: Sony Corporation, Tokyo (JP)

(21) Appl. No.: 14/219,485

(22) Filed: Mar. 19, 2014

(30) Foreign Application Priority Data
Mar. 27, 2013 (JP) 2013-066220

(51) Int. Cl. H01L 27/146; H01L 27/01

(52) U.S. Cl. CPC H01L 27/14612; H01L 27/016
USPC 257/43; 257/53; 257/72

(57) ABSTRACT

An image pickup device that includes: a pixel section including a plurality of pixels each configured to generate a signal charge based on radiation; a first field-effect transistor provided in the pixel section; and a second field-effect transistor provided in a peripheral circuit section of the pixel section. The first transistor has a threshold voltage and the second transistor has a threshold voltage that are different from each other.

### CROSS REFERENCE TO RELATED APPLICATIONS

This application claims the benefit of Japanese Priority Patent Application JP 2013-066220 filed on Mar. 27, 2013, the entire contents of which are incorporated herein by reference.

### BACKGROUND

The present disclosure relates to an image pickup device that includes a photoelectric conversion element and an image pickup display system that includes such an image pickup device.

Recently, various image pickup devices of a type that the photoelectric conversion element is built in each pixel (an image pickup pixel) are proposed. One example of such an image pickup device may include, for example, a so-called optical touch panel, a radiographic image pickup device and so forth (for example, Japanese Unexamined Patent Application Publication No. 2011-135561).

### SUMMARY

Although in such an image pickup device as described above, a thin film transistor (TFT: Thin Film Transistor) is used as a switching element adapted to read out a signal charge from each pixel, such a disadvantage may occur that the reliability is reduced due to shifting of the threshold voltage of the TFT.

It is desirable to provide an image pickup device that makes is possible to achieve high reliability by mitigating an influence caused by shifting of a threshold voltage of a transistor, and an image pickup display system that includes such an image pickup device.

According to an embodiment of the present disclosure, there is provided an image pickup device including: a pixel section including a plurality of pixels, each of the pixels being configured to generate a signal charge based on radiation; a first field-effect transistor provided in the pixel section; and a second field-effect transistor provided in a peripheral circuit section of the pixel section. The first transistor has a threshold voltage and the second transistor has a threshold voltage that are different from each other.

According to an embodiment of the present disclosure, there is provided an image pickup display system provided with an image pickup device and a display configured to perform image display based on an image pickup signal obtained by the image pickup device. The image pickup device includes: a pixel section including a plurality of pixels each configured to generate a signal charge based on radiation; a first field-effect transistor provided in the pixel section; and a second field-effect transistor provided in a peripheral circuit section of the pixel section. The first transistor has a threshold voltage and the second transistor has a threshold voltage that are different from each other.

In the image pickup device and the image pickup display system according to the above-described embodiments of the present disclosure, the threshold voltage of the first transistor, provided in the pixel section that includes the plurality of pixels each of which generates the radiation-based signal charge, is made different from the threshold voltage of the second transistor provided in the peripheral circuit section of the pixel section. Thus, it is possible to set the respective threshold voltages of the first and the second transistors in anticipation of, for example, threshold voltage shifting of the transistor which would be more liable to occur in the pixel section than in the peripheral circuit section, and therefore the life property of the transistor is improved.

According to the image pickup device and the image pickup display system in the above-described embodiments of the present disclosure, the threshold voltage of the first transistor, provided in the pixel section that includes the plurality of pixels each of which generates the radiation-based signal charge, is made different from the threshold voltage of the second transistor provided in the peripheral circuit section of the pixel section. Thus, it is possible to set the respective threshold voltages of the first and the second transistors in anticipation of, for example, threshold voltage shifting of the transistor which would be more liable to occur in the pixel section than in the peripheral circuit section, and to improve the life property of the transistor. Therefore, it is possible to achieve high reliability by mitigating an influence caused by shifting of the threshold voltage of the transistor.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a block diagram illustrating one general configuration example of an image pickup device according to one embodiment of the present disclosure.

FIG. 2 is a circuit diagram illustrating one detailed configuration example of a pixel and so forth illustrated in FIG. 1.

FIG. 3 is a sectional diagram illustrating one schematic configuration example of a photoelectric conversion element and a transistor illustrated in FIG. 2.

FIG. 4 is a block diagram illustrating one detailed configuration example of a row scanning section illustrated in FIG. 1.

FIG. 5 is a block diagram illustrating one detailed configuration example of a column selection section illustrated in FIG. 1.

FIG. 6A is a characteristic diagram illustrating one example of current-voltage characteristics of transistors in a pixel section and a peripheral circuit section.

FIG. 6B is a characteristic diagram for explaining one example of an operating point of a P-channel type transistor.

FIG. 7A is a sectional diagram for explaining one example of a method of setting the operating points of the transistors in the pixel section and the peripheral circuit section.

FIG. 7B is a sectional diagram for explaining one example of a process following a process in FIG. 7A.

FIG. 7C is a sectional diagram for explaining one example of a process following the process in FIG. 7B.

FIG. 7D is a sectional diagram for explaining one example of a process following the process in FIG. 7C.

FIG. 7E is a sectional diagram for explaining one example of a process following the process in FIG. 7D.

FIG. 7F is a sectional diagram for explaining one example of a process following the process in FIG. 7E

FIG. 7G is a sectional diagram for explaining one example of a process following the process in FIG. 7F.

FIG. 8 is a current-voltage characteristic diagram for explaining one example of threshold voltage shifting caused by X-ray irradiation.

FIG. 9 is a characteristic diagram illustrating one example of a relation between an X-ray cumulative irradiation amount (dose) and a threshold voltage shift amount.

FIG. 10A is a sectional diagram for explaining one example of a method of setting the operating point of a transistor according to a modification example 1 of the present disclosure.

FIG. 10B is a sectional diagram for explaining one example of a process following a process in FIG. 10A.

FIG. 10C is a sectional diagram for explaining one example of a process following the process in FIG. 10B.

FIG. 10D is a sectional diagram for explaining one example of a process following the process in FIG. 10C.

FIG. 10E is a sectional diagram for explaining one example of a process following the process in FIG. 10D.

FIG. 11 is a sectional diagram illustrating one configuration example of a transistor according to a modification example 2 of the present disclosure.

FIG. 12 is a circuit diagram illustrating one configuration example of a pixel and so forth according to a modification example 3 of the present disclosure.

FIG. 13 is a circuit diagram illustrating one configuration example of a pixel and so forth according to a modification example 4-1 of the present disclosure.

FIG. 14 is a circuit diagram illustrating one configuration example of a pixel and so forth according to a modification example 4-2 of the present disclosure.

FIG. 15A is schematic diagram for explaining one example of an image pickup device according to a modification example 5-1.

FIG. 15B is a schematic diagram for explaining one example of an image pickup device according to a modification example 5-2.

FIG. 16A is a sectional diagram for explaining one example of an advantage of a transistor according to another modification example.

FIG. 16B is a sectional diagram for explaining one example of the advantage of the transistor according to the above-mentioned another modification example.

FIG. 16C is a sectional diagram for explaining one example of the advantage of the transistor according to the above-mentioned another modification example.

FIG. 16D is a sectional diagram for explaining one example of the advantage of the transistor according to the above-mentioned another modification example.

FIG. 16E is a sectional diagram for explaining one example of the advantage of the transistor according to the above-mentioned another modification example.

FIG. 17 is a schematic diagram illustrating one schematic configuration example of an image pickup display system according to an application example of the present disclosure.

### DETAILED DESCRIPTION

In the following, some embodiments of the present disclosure will be described in detail with reference to the accompanying drawings. It is to be noted that description will be made in the following order.

1. Embodiment (one example of an image pickup device in which a threshold voltage of a transistor of a pixel section is set to a value that is shifted from a value of a threshold voltage of a transistor of a peripheral circuit section to a positive side)
2. Modification Example 1 (another example of a threshold voltage setting method)
3. Modification Example 2 (one configuration example of a dual gate type transistor)
4. Modification Example 3 (one example of another passive type pixel circuit)
5. Modification Examples 4-1 and 4-2 (examples of active type pixel circuits)
6. Modification Examples 5-1 and 5-2 (examples of indirect conversion type and direct conversion type radiographic image pickup devices)
7. Application Example (one example of an image pickup display system)

### Embodiment

### [General Configuration of Image Pickup Device 1]

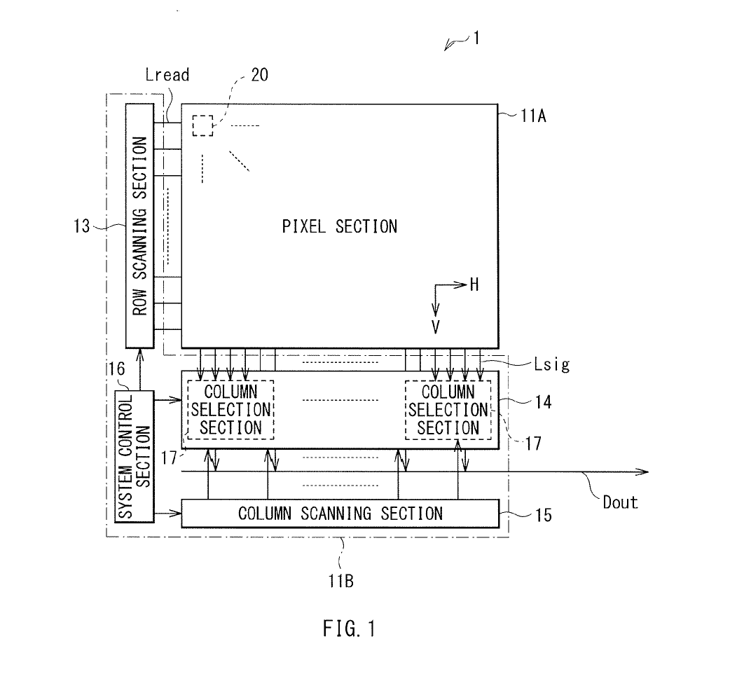

FIG. 1 is a block diagram illustrating one general configuration example of an image pickup device (the image pickup device 1) according to one embodiment of the present disclosure. The image pickup device 1 may be adapted to read out information of an object (picks up an image of the object) on the basis of incident light (image pickup light) such as, for example, radiation and so forth. The image pickup device 1 includes a pixel section 11A, and also includes a row scanning section 13, an A/D conversion section 14, a column scanning section 15, and a system control section 16 as a peripheral circuit section 11B of the pixel section 11A. In the image pickup device 1, a shield layer for intersecting the radiation, that is, a metal shield layer which may be made of, for example, lead (Pb), and/or tungsten (W) and so forth may be provided in a region (for example, a bezel region) corresponding to the peripheral circuit section 11B.

### (Pixel Section 11A)

The pixel section 11A is adapted to generate an electric signal in accordance with the incident light (the image pickup light). In the pixel section 11A, pixels (image pickup pixels or unit pixels) 20 are two-dimensionally arranged in a row by column form (in a matrix), and each pixel 20 includes a photoelectric conversion element (a later described photoelectric conversion element 21) that generates photocharges (signal charges) of a charge amount according to a light amount (a received light amount) of the incident light. It is to be noted that in the following, a horizontal direction (a row direction) and a vertical direction (a column direction) in the pixel section 11A will be described respectively as an “H” direction and a “V” direction as illustrated in FIG. 1.

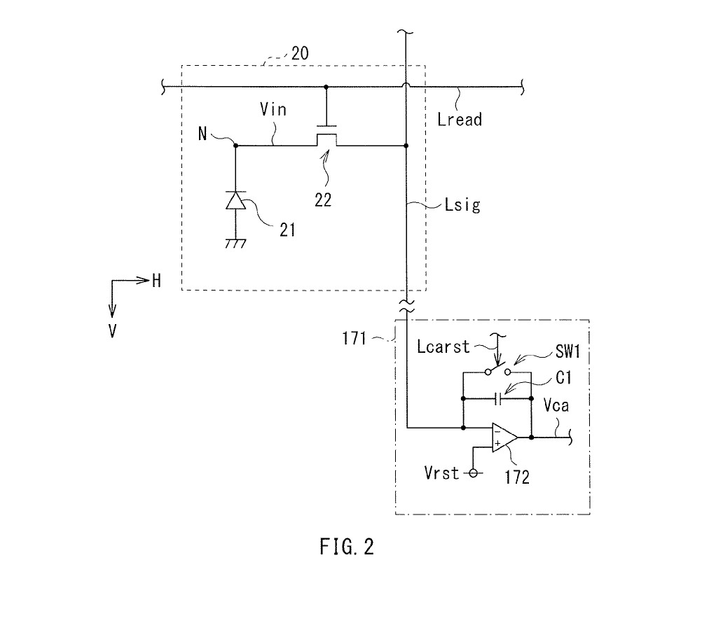

FIG. 2 is a diagram illustrating one example of a circuit configuration (a so-called passive type circuit configuration) of the pixel 20 together with one circuit configuration example of a later described column selection section 17 in the A/D conversion section 14. The passive type pixel 20 includes one photoelectric conversion element 21 and one transistor 22. In addition, a read-out control line Lread that extends along the H direction and a signal line Lsig that extends along the V direction are connected to the pixel 20.

The photoelectric conversion element 21 may be configured by, for example, a PIN (Positive Intrinsic Negative) type photodiode or a MIS (Metal-Insulator-Semiconductor) type sensor, and is adapted to generate the signal charges of the charge amount according to the incident light amount as described above. It is to be noted that a cathode of the photoelectric conversion element 21 is connected to an accumulation node N in the example illustrated in FIG. 2.

The transistor 22 is a transistor (a read-out transistor) that is turned ON in accordance with a row scanning signal supplied from the read-out control line Lread to output a signal charge (an input voltage Vin) obtained by the photoelectric conversion element 21 to the signal line Lsig. In the example in FIG. 2, the transistor 22 is configured by an N-channel type (N-type) field-effect transistor (FET: Field-effect Transistor). Alternatively, the transistor 22 may be configured by a P-channel type (P-type) FET and so forth.

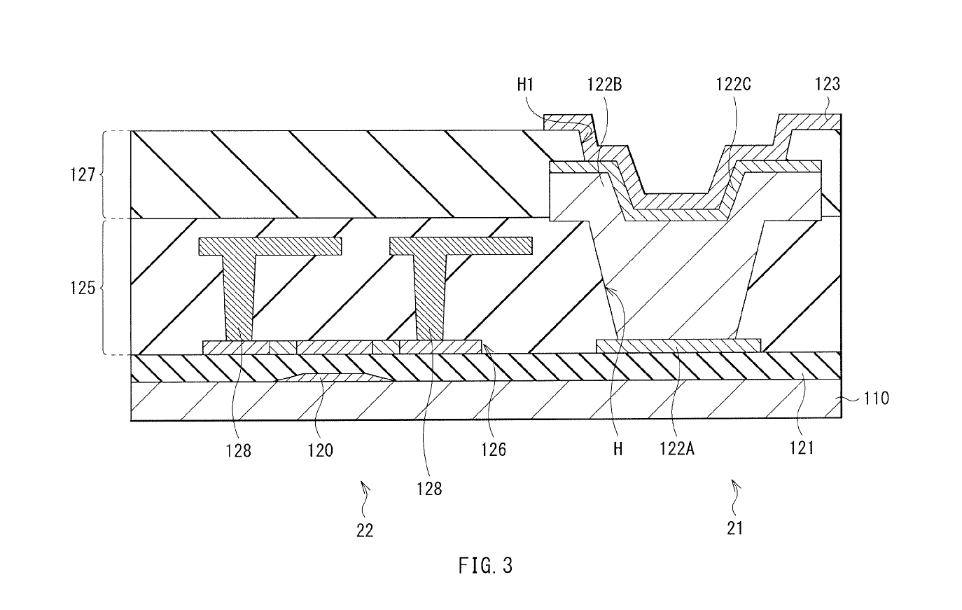

FIG. 3 illustrates one sectional structure example of the photoelectric conversion element 21 and the transistor 22. The photoelectric conversion element 21 includes a p-type semiconductor layer 122A in a selective region on a substrate 110 which may be made of glass and so forth via a gate insulating film 121. An interlayer insulating film 125 that includes a contact hole (a through-hole) H is provided on the substrate 110 (on the gate insulating film 121 in more detail), facing the n-type semiconductor layer 122A. An i-type semiconductor layer 122B is embedded in the contact hole H in the interlayer insulating film 125, and the i-type semiconductor layer 122B is in contact with the p-type semiconductor layer 122A. An n-type semiconductor layer 122C is formed on the i-type semiconductor layer 122B. An interlayer insulating film 127 is formed on the n-type semiconductor layer 122C, and an upper electrode 123 is electrically connected to the n-type semiconductor layer 122C via a contact hole H1 of the interlayer insulating film 127. It is to be noted that, here, one example in which the p-type semiconductor layer 122A and the n-type semiconductor layer 122C have been provided respectively on a substrate side (a lower side) and on an upper side is given, an inverted structure, that is, a structure that the n-type semiconductor layer is provided on the lower side (the substrate side) and the p-type semiconductor layer is provided on the upper side may be also possible.

The gate insulating film 121 may be formed as a film that has the same layer structure as, for example, a gate insulating film of the later described transistor 22. The gate insulating film 121 may be a single layer film configured by any one of, for example, a silicon oxide film (SiOₓ), a silicon nitride film (SiNₓ), a silicon oxynitride film (SiON) and so forth, or may be a laminated film configured by two or more of the above-mentioned films.

The p-type semiconductor layer 122A may be a p+ region which may be configured by doping, for example, boron (B) into, for example, polycrystalline silicon (poly-silicon) or microcrystalline silicon, and may have a thickness of, for example, about 40 nm to about 50 nm both inclusive. The p-type semiconductor layer 122A may also function as a lower electrode (for example, an anode) adapted to read out, for example, the signal charge.

Each of the interlayer insulating films 125 and 127 may be a single layer film which may be configured by any one of, for example, a silicon oxide film, a silicon nitride film, a silicon oxynitride film and so forth, or may be a laminated film configured by two or more of the above-mentioned films. The interlayer insulating film 125 may be formed so as to extend up to, for example, a region in which the transistor 22 is formed.

The i-type semiconductor layer 122B may be, for example, a non-doped intrinsic semiconductor layer and may be configured by, for example, non-crystalline silicon (amorphous silicon). Although a thickness of the i-type semiconductor layer 122B may be, for example, about 400 nm to about 1000 nm both inclusive, the thicker the thickness is, the more it becomes possible to increase light sensitivity. The n-type semiconductor layer 122C may be configured by, for example, non-crystalline silicon (amorphous silicon) and may form an n+ region. A thickness of the n-type semiconductor layer 122C may be, for example, about 10 nm to about 50 nm both inclusive.

The upper electrode 123 (a cathode) may be configured by a transparent conductive film made of, for example, ITO (Indium Tin Oxide) and so forth. In the example in FIG. 3, the upper electrode 123 may be electrically connected to the transistor 22 via, for example, the accumulation node N.

In the transistor 22, a gate electrode 120 which may be made of, for example, molybdenum (Mo), titanium (Ti), aluminum (Al), tungsten (W), and/or chromium (Cr) and so forth may be formed in a selective region on the substrate 110, and the gate insulating film 121 is formed on the gate electrode 120, extending from a region in which the above-mentioned photoelectric conversion element 21 is formed. A semiconductor layer 126 is formed in a region facing the gate electrode 120 on the gate insulating film 121.

The semiconductor layer 126 forms a channel region and is electrically connected to a source-drain electrode 128 that functions as a source or a drain. The semiconductor layer 126 may be configured by a silicon based semiconductor such as, for example, non-crystalline silicon (amorphous silicon), microcrystalline silicon, and/or polycrystalline silicon (poly-silicon) and so forth, and desirably configured by low temperature polycrystalline silicon (LTPS: Low Temperature Poly-silicon). Alternatively, the semiconductor layer 126 may be configured by an oxide semiconductor such as, for example, indium gallium zinc oxide (InGaZnO) and/or zinc oxide (ZnO) and so forth. The source-drain electrode 128 may be made of, for example, titanium (Ti), aluminum (Al), molybdenum (Mo), tungsten (W), and/or chromium (Cr) and so forth.

In the present embodiment, a threshold voltage of the transistor 22 (a first transistor) provided in the pixel 20 (the pixel section 11A) that includes the photoelectric conversion element 21 as mentioned above and a threshold voltage of a transistor provided in the peripheral circuit section 11B (in detail, a transistor having the same element structure as the transistor 22 in transistors in the peripheral circuit section 11B, i.e., a second transistor which is not illustrated in FIG. 3) are different from each other. In other words, operating points of the transistors are different from each other between the pixel section 11A and the peripheral circuit section 11B, in detail, pulse voltages (ON voltage and OFF voltage) used to make a switch between an OFF state and an ON state of the transistors are different from each other. A method of setting the operating point of the transistor 22 will be described later.

### (Row Scanning Section 13)

The row scanning section 13 is a pixel drive section (a row scanning circuit) that includes later described shift register circuit, predetermined logic circuit and so forth, and adapted to perform row-by-row (in units of horizontal lines) driving (line sequential scanning) on the plurality of pixels 20 in the pixel section 11A. Specifically, image picking-up operations such as a reading-out operation, a resetting operation and so forth to be performed on each pixel 20 may be performed by, for example, line sequential scanning. It is to be noted that the line sequential scanning is performed by supplying the aforementioned row scanning signal to each pixel 20 via the read-out control line Lread.

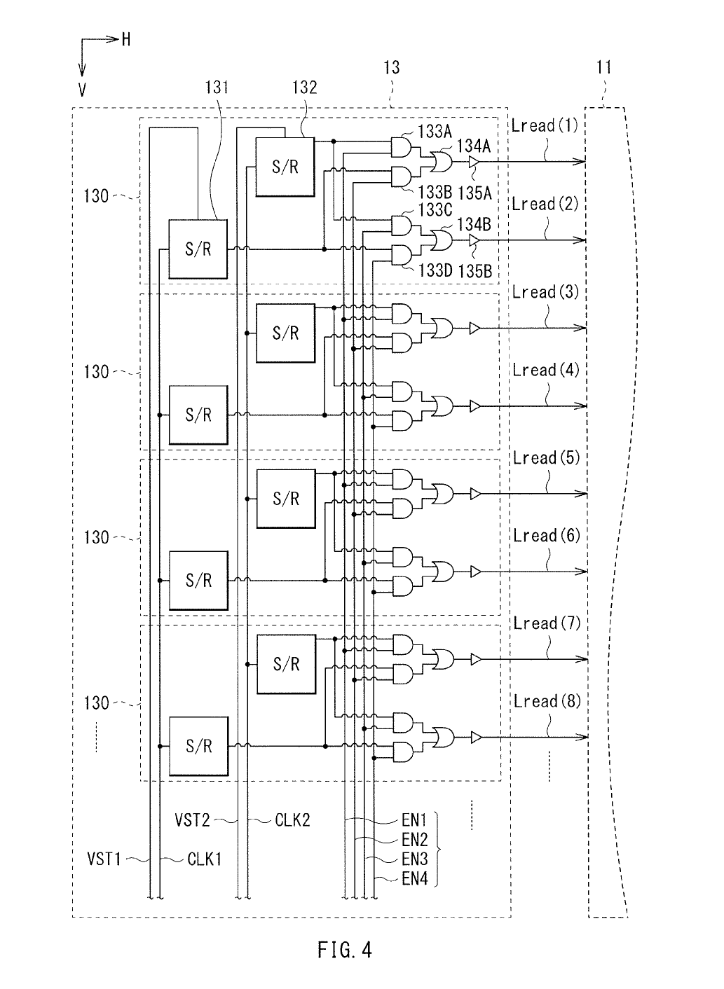

FIG. 4 is a block diagram illustrating one configuration example of the row scanning section 13. The row scanning section 13 includes a plurality of unit circuits 130 that extend along the V direction. It is to be noted that in the example illustrated in FIG. 4, eight read-out control lines Lread that are connected to four unit circuits 130 illustrated in the drawing are denoted by Lread(1) to Lread(8) from top to bottom.

Each unit circuit 130 may include, for example, one or a plurality of columns (here, two columns) of shift register circuits 131 and 132 (abbreviated to “S/R” in the block in the drawing for convenience; the same shall apply hereinafter), four AND circuits (logical product circuits) 133A to 133D, two OR circuits (logical sum circuits) 134A and 134B, and two buffer circuits 135A and 135B. Although a configuration in which two columns of the shift register circuits are included will be described by way of example here, the unit circuit may be configured by one column of the shift register circuits. However, through not described in detail, it becomes possible to perform the resetting operation a plurality of times in one frame period by providing two or more columns of the shift register circuits.

The shift register circuit 131 is a circuit adapted to generate a pulse signal for sequentially shifting the plurality of unit circuits 130 as a whole in the V direction on the basis of a start pulse VST1 and a clock signal CLK1 supplied from the system control section 16, Likewise, the shift register circuit 132 is a circuit adapted to generate a pulse signal for sequentially shifting the plurality of unit circuits 130 as a whole in the V direction on the basis of a start pulse VST2 and a clock signal CLK2 supplied from the system control section 16, Thus, for example, the shift register circuit 131 may generate the pulse signal for first reset driving and the shift register circuit 132 may generate the pulse signal for second reset driving.

Four enable signals EN1 to EN4 for controlling (defining) validity periods of the respective pulse signals (respective output signals) output from the shift register circuits 131 and 132 are respectively input into the AND circuits 133A to 133D. Specifically, the pulse signal from the shift register circuit 132 is input into one input terminal and the enable signal EN1 is input into the other input terminal in the AND circuit 133A. The pulse signal from the shift register circuit 131 is input into one input terminal and the enable signal EN2 is input into the other input terminal in the AND circuit 133B. The pulse signal from the shift register circuit 132 is input into one input terminal and the enable signal EN3 is input into the other input terminal in the AND circuit 133C. The pulse signal from the shift register circuit 131 is input into one input terminal and the enable signal EN4 is input into the other input terminal in the AND circuit 133D.

The OR circuit 134A is a circuit adapted to generate a logical sum signal (an OR signal) of an output signal from the AND circuit 133A and an output signal from the AND circuit 133B. Likewise, the OR circuit 134B is a circuit adapted to generate a logical sum signal (the OR signal) of an output signal from the AND circuit 133C and an output signal from the AND circuit 133D. The logical sum signals of the output signals (the pulse signals) output from the shift register circuits 131 and 132 are generated by the above-mentioned AND circuits 133A to 133D and the OR circuits 134A and 134B in the above mentioned manner while controlling the validity periods of the respective output signals. Thus, respective driving timings and so forth, for example, when the reset driving is to be performed the plurality of times may be defined.

The buffer circuit 134A is a circuit that functions as a buffer for the output signal (the pulse signal) from the OR circuit 134A, and the buffer circuit 134B is a circuit that functions as a buffer for the output signal (the pulse signal) from the OR circuit 134B. The pulse signals (the row scanning signals) so buffered by the buffer circuits 135A and 135B are output to the respective pixels 20 in the pixel section 11A via the read-out control lines Lread.

### (A/D Conversion Section 14)

The A/D conversion section 14 includes the plurality of column selection sections 17 that are provided one for every plurality of (here, four) signal lines Lsig, and is adapted to perform A/D conversion (analog/digital conversion) on the basis of a signal voltage (a voltage according to each signal charge) input via the signal line Lsig. Thus, output data Dout (image pickup signal) configured by a digital signal is generated and output to the outside.

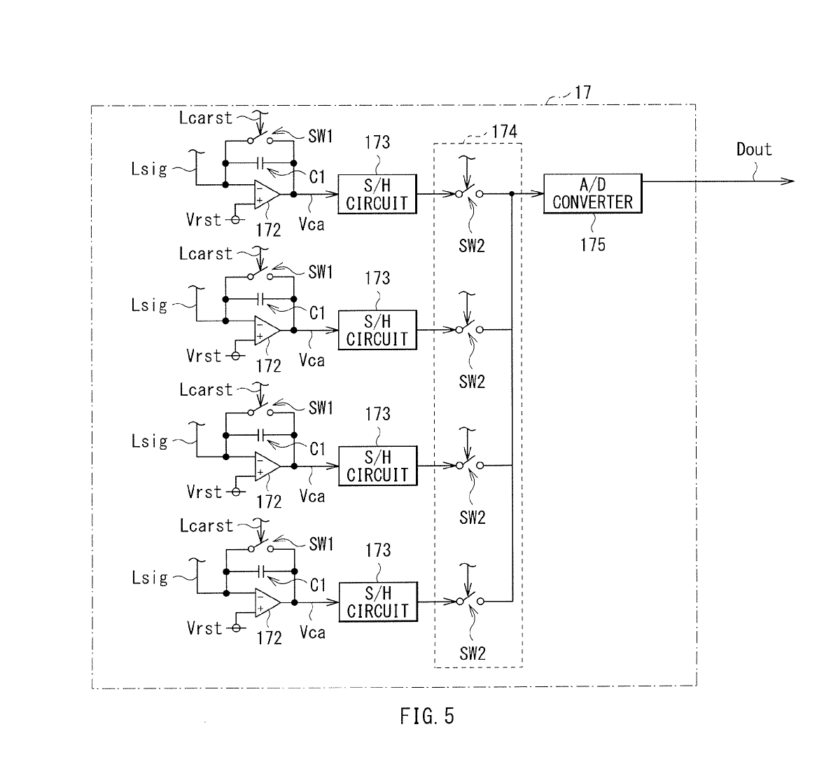

For example, as illustrated in FIG. 2 and FIG. 5, each column selection section 17 includes a charge amplifier 172, a capacitor (such as a feedback capacitor) C1, a switch SW1, a sample/hold (S/H) circuit 173, a multiplexer circuit (a selection circuit) 174 that includes four switches SW2, and an A/D converter 175. In the above-mentioned constitutional elements, the charge amplifier 172, the capacitor C1, the switch SW1, the S/H circuit 173, and the switch SW2 are provided for every signal line Lsig, and the multiplexer circuit 174 and the A/D converter 175 are provided for every column selection section 17.

The charge amplifier 172 is an amplifier adapted to convert (Q-V convert) the signal charge read out from the signal line Lsig into a voltage. The charge amplifier 172 is configured such that one end of the signal line Lsig is connected to a negative side (− side) input terminal and a predetermined reset voltage Vrst is input into a positive side (+ side) input terminal. An output terminal and the negative side input terminal of the charge amplifier 172 are feedback-connected with each other via a circuit configured by parallel-connecting the capacitor C1 and the switch SW1. That is, one terminal of the capacitor C1 is connected to the negative side input terminal of the charge amplifier 172 and the other terminal of the capacitor C1 is connected to the output terminal of the charge amplifier 172. Likewise, one terminal of the switch SW1 is connected to the negative side input terminal of the charge amplifier 172 and the other terminal of the switch SW1 is connected to the output terminal of the charge amplifier 172. It is to be noted that the ON/OFF state of the switch SW1 is controlled by a control signal (an amplifier reset control signal) supplied from the system control section 16 via an amplifier reset control line Lcarst.

The S/H circuit 173 is provided between the charge amplifier 172 and the multiplexer circuit 174 (the switch SW2), and is a circuit adapted to temporarily hold an output voltage Vca from the charge amplifier 172.

The multiplexer circuit 174 is a circuit adapted to selectively establish or cut off connection between each S/H circuit 173 and each A/D converter 175 by sequentially turning ON the four switches SW2 one by one in accordance with scan driving by the column scanning section 15.

The A/D converter 175 is a circuit adapted to generate and output the above-mentioned output data Dₒᵤₜ by performing A/D conversion on the output voltage that has been output from the S/H circuit 173 and input into the A/D converter 175 via the switch SW2.

### (Column Scanning Section 15)

The column scanning section 15 may include, for example, not illustrated shift register, address decoder and so forth, and is adapted to drive in order the respective switches SW2 in the above-mentioned column selection section 17 while scanning the switches SW2. Signals (the above-mentioned output data Dout) that have been read out from the respective pixels 20 via the respective signal lines Lsig are output to the outside in order by such selective scanning by the column scanning section 15 as mentioned above.

### (System Control Section 16)

The system control section 16 is adapted to control respective operations of the row scanning section 13, the A/D conversion section 14, and the column scanning section 15. Specifically, the system control section 16 includes a timing generator for generating the aforementioned various timing signals (the control signals), and controls driving of the row scanning section 13, the A/D conversion section 14, the column scanning section 15, and a bias voltage correction section 18 on the basis of the various timing signals generated by the timing generator. The image pickup device 1 is configured such that the row scanning section 13, the A/D conversion section 14, and the column scanning section 15 each perform image pickup driving (line sequential image pickup driving) on the plurality of pixels 20 within the pixel section 11A on the basis of the control by the system control section 16 so as to acquire the output data Dout from the pixel section 11A.

### (Setting of Transistor Operating Points)

In the present embodiment, the operating points (the threshold voltages) of the transistors are made different from each other between the pixel section 11A and the peripheral circuit section 11B as described above. It is to be noted that in the following, the transistor 22 provided in the pixel section 11A will be referred to as a “transistor TrA” and the transistor 22 provided in the peripheral circuit section 11B will be referred to as a “transistor TrB” for the convenience of description. In the present embodiment, the transistor TrA in the pixel 20 (the pixel section 11A) is a so-called bottom gate type transistor as illustrated in FIG. 3, and the transistor TrB in the peripheral circuit section 11B may be configured as, for example, the bottom gate type transistor similarly. However, each of the transistors TrA and TrB may be configured as, for example, a top gate type transistor, or a so-called dual (double-sided) gate type transistor (described in detail later) in which two gate electrodes are provided with the semiconductor layer 126 interposed in between, not limited to the bottom gate type transistor. In addition, the transistors TrA and TrB may be either the same as each other or different from each other in such element structure (the bottom gate type, top gate type, or dual gate type element structure). For example, as in the present embodiment, both of the transistors TrA and TrB may be of the bottom gate type, or both of the transistors may be of either the top gate type or the dual gate type.

In addition, for example, when the transistors TrA and TrB are different from each other in element structure, it may be desirable that, for example, the transistor TrA be of the dual gate type and the transistor TrB be of the top gate type or the bottom gate type. Although X-ray resistivity is more requested in the pixel section 11A than in the peripheral circuit section 11B, the dual gate type element structure is higher in X-ray resistivity than the top gate type and bottom gate type element structures. On the other hand, a pattern failure (the pattern failure in formation of electrodes, wirings and so forth) is more liable to occur in the dual gate type element structure than in the top gate type and bottom gate type element structures. Therefore, it is preferable that the top gate type or bottom gate type element structure be adopted in the peripheral circuit section 11B that the X-ray resistivity is not requested so much in comparison with the pixel section 11A.

In this regard, when such a pattern failure as mentioned above occurs in the transistor having the dual gate type element structure, a so-called line defect may sometimes occur caused by this pattern failure. In standards for a FPD (flat panel display) that picks up images with X-rays, although the standard for point defects is lenient, the line defects are listed as delinquent items. In addition, although it is possible to compensate for one line defect (when the line defect is present alone) by preforming image interpolation processing and so forth, it becomes difficult to perform interpolation processing on two or more line defects (when the two or more line defects are present adjacently). Since it is possible to perform repair processing in the pixel section 11A even when the line defect occurs due to adoption of the dual gate type element structure, it is possible to suppress an influence caused by the line defect by performing the repair processing.

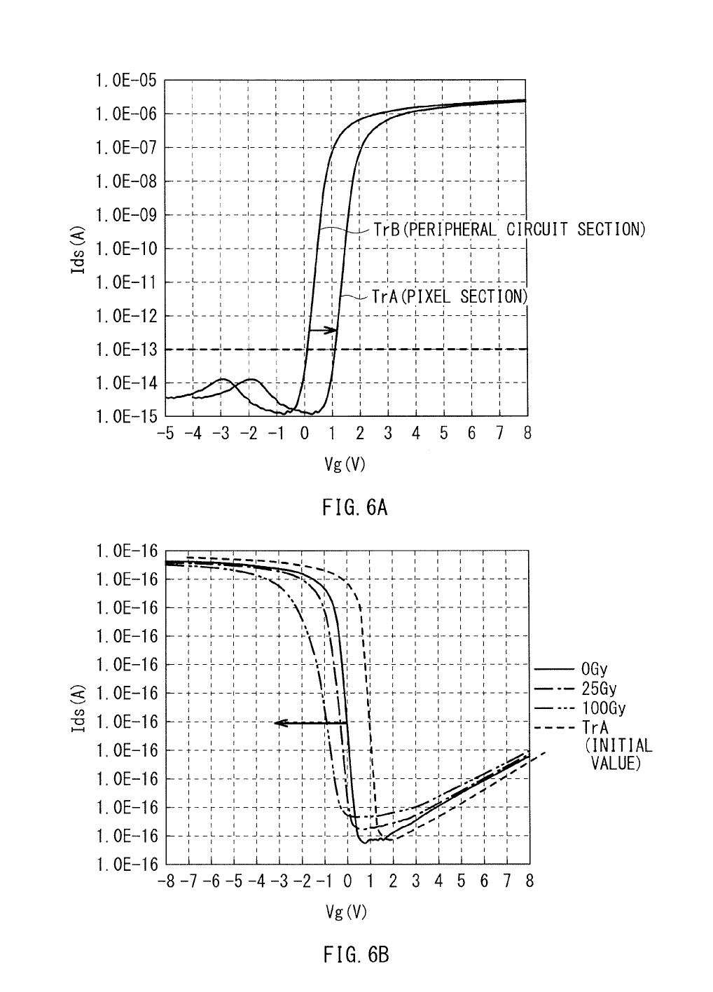

FIG. 6A illustrates one example of IV characteristics (relation between a source-drain current Ids (A) and a gate voltage Vg (v): current-voltage characteristics) of the transistor TrA of the pixel section 11A and the transistor TrB of the peripheral circuit section 11B. As illustrated in the drawing, the transistor TrA of the pixel section 11A exhibits the IV characteristic that is shifted from the IV characteristic of the transistor TrB of the peripheral circuit section 11B to the positive side (the + side). That is, in the present embodiment, the threshold voltage (the voltage Vg obtained, for example, when the current Ids may be about 1.0×10⁻¹³ (A); hereinafter referred to as a threshold voltage Vth0) is set using a voltage of the transistor TrB as a reference. The threshold voltage (referred to as a threshold voltage Vth1) of the transistor TrA is set to a value that is shifted from a value of the threshold voltage Vth0 of the transistor TrB to the positive side. A shift amount of the threshold voltage Vth1 from the threshold voltage Vth0 is set to an appropriate value in accordance with various parameters such as an expected cumulative irradiation amount (dose) of X-rays to the pixel section 11A and/or a thickness of the gate insulating film 121 (the silicon oxide film) and so forth. In this example, the shift amount of, for example, about +(plus) 1 (one) V may be set. It is to be noted that although an example that the transistors TrA and TrB are N-channel type transistors is illustrated in FIG. 6A, the threshold voltage Vth0 may be shifted to the negative side in accordance with the X-ray cumulative irradiation amount as in the case of the N channel type transistors even when the transistor TrA is of a P-channel type, for example, as illustrated in FIG. 6B. Therefore, the threshold voltage Vth1 (indicated by a broken line in the drawing) of the transistor TrA may be set to a value that is shifted from a value of the threshold voltage Vth0 to the positive side also in case of the P-channel type transistor. As for the operating points of the transistor TrA in the example in FIG. 6B, an ON operating point is set to −7V and an OFF operating point is set to +4V.

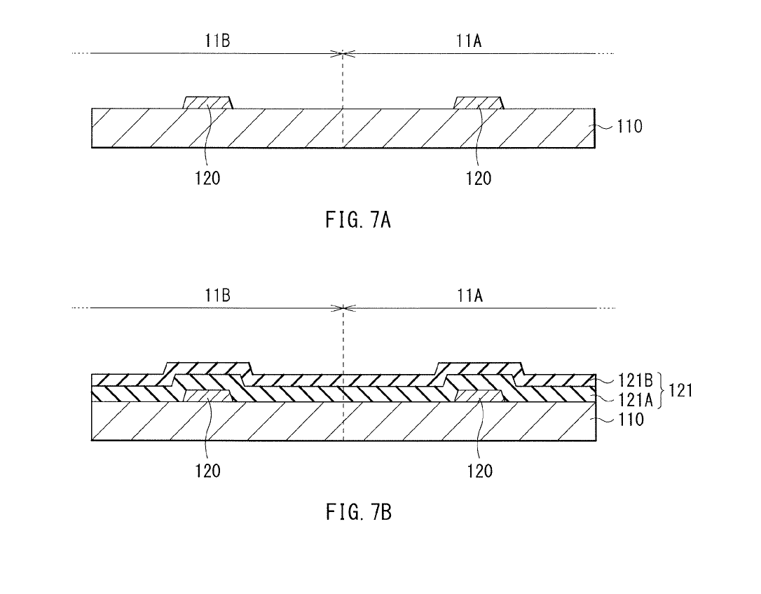

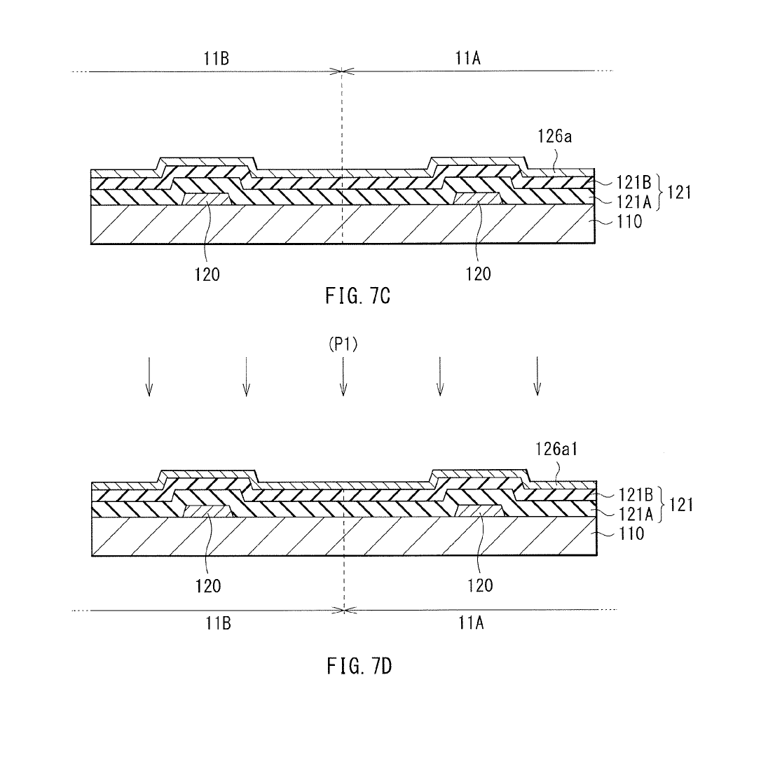

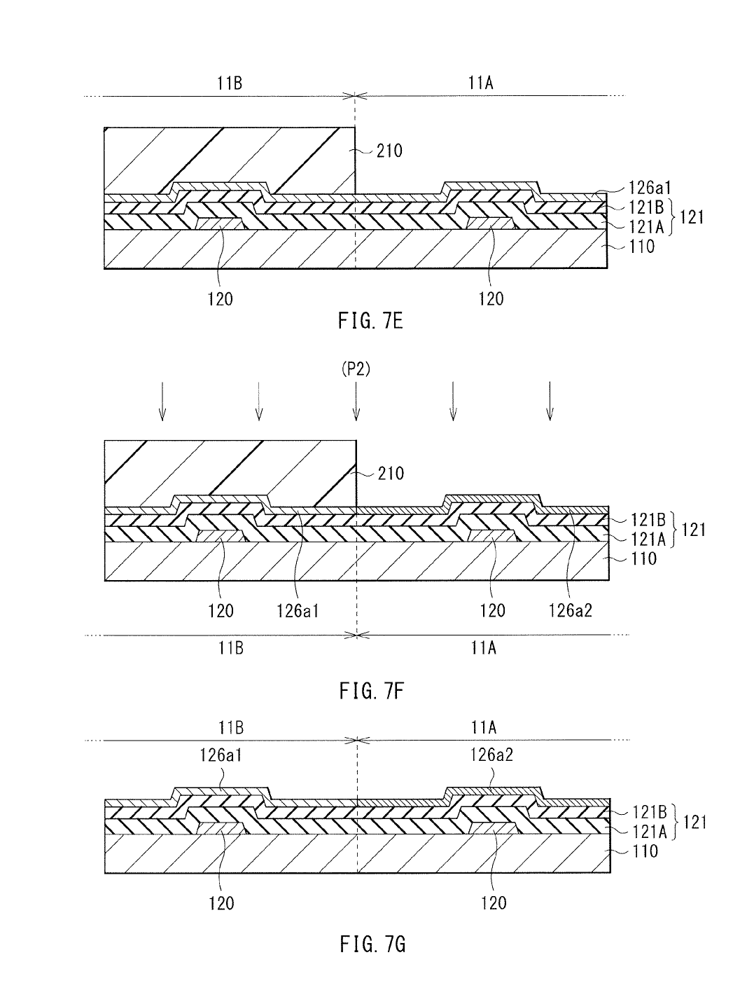

The threshold voltages Vth0 and Vth1 of the transistors TrA and TrB as mentioned above may be set, for example, as follows. A method of setting the threshold voltages is illustrated in FIG. 7A to FIG. 7G in order of processes to be performed. The threshold voltages Vth0 and Vth1 as mentioned above may be set, for example, in a process of forming the transistors of the pixel section 11A and the peripheral circuit section 11B. Specifically, the threshold voltage may be shifted by changing the impurity concentration of the semiconductor layer 126.

That is, first, a gate electrode 120 is formed in a selective region on the substrate 110 in each of the pixel section 11A and the peripheral circuit section 11B as illustrated in FIG. 7A. Thereafter, a gate insulating film 121 is formed on the substrate 110 so as to cover the gate electrode 120 as illustrated in FIG. 7B. As the gate insulating film 121, a laminated film which may be configured by, for example, a silicon nitride film 121A and a silicon oxide film 121B may be used. The silicon nitride film 121A and the silicon oxide film 121B may be formed by, for example, a CVD (Chemical Vapor Deposition) method.

Then, a semiconductor layer 126a that may contain, for example, polycrystalline silicon is formed as illustrated in FIG. 7C. Thereafter, impurity diffusion is performed on the semiconductor layer 126a by so-called ion implantation (first ion implantation (P1)) as illustrated in FIG. 7D. Thus, a semiconductor layer 126a1 having a predetermined impurity concentration is formed over the whole regions of the pixel section 11A and the peripheral circuit section 11B.

Then, only the peripheral circuit section 11B is selectively masked out of the pixel section 11A and the peripheral circuit section 11B as illustrated in FIG. 7E. For example, after forming a photoresist film over the entire surface of the substrate 110, a photoresist film 210 may be formed only in the peripheral circuit section 11B by performing patterning through selective light exposure.

Thereafter, further impurity diffusion is performed on the semiconductor layer 126a1 by second ion implantation (P2) as illustrated in FIG. 7F. Thus, the impurities are doped into a selective part of the semiconductor layer 126a1 corresponding to the pixel section 11A. As a result, it becomes possible to form the semiconductor layer 126a2 having the impurity concentration (higher in impurity concentration than the semiconductor layer 126a1) which is different from the impurity concentration of the semiconductor layer 126a1 in the pixel section 11A. It is to be noted that the semiconductor layers 126a1 and 126a2 correspond to the semiconductor layer 126 of the above-mentioned transistor 22.

Finally, the photoresist film 210 is removed as illustrated in FIG. 7G The impurity concentration of the semiconductor layer 126a2 of the pixel section 11A (the transistor TrA) is made higher than the impurity concentration of the semiconductor layer 126a1 of the peripheral circuit section 11B (the transistor TrB) in this way. It is possible to form the transistors TrA and TrB having the threshold voltages Vth0 and Vth1 as described above by performing the impurity diffusion process two times in this way. It is to be noted that after formation of the above-mentioned semiconductor layers 126a1 and 126a2 (the semiconductor layer 126), the bottom gate type transistors TrA and TrB are formed by forming the interlayer insulating film 125 and the source-drain electrode 128.

### [Functions and Effects]

In the image pickup device 1 of the present embodiment, for example, when the radiation or radiation-based light is incident upon the pixel section 11A, the signal charge which is based on the incident light is generated (photoelectric conversion is performed) in the photoelectric conversion element 21 in each pixel 20. Describing in detail, a voltage change according to the node capacity occurs by accumulation of the signal charges generated by photoelectric conversion in the accumulation node at that time. The input voltage Vin (the voltage corresponding to the signal charge) is supplied to a drain of the transistor 22 in accordance with such a voltage change as mentioned above. Then, when the transistor 22 is turned ON in accordance with the row scanning signal supplied from the read-out control line Lread, the above-mentioned signal charge is read out to the signal line Lsig.

The signal charges so read-out are input into the column selection sections 17 in the A/D conversion section 14 in units of a plurality of (here, four) pixel columns via the signal lines Lsig. In the column selection section 17, first, Q-V conversion (conversion from the signal charge to the signal voltage) is performed by a charge amplifier circuit configured by the charge amplifier 172 and so forth on each signal charge input from each signal line Lsig. Then, A/D conversion is performed on each signal voltage so converted (each output voltage Vca from the charge amplifier 172) by the A/D converter 175 via the S/H circuit 173 and the multiplexer circuit 174 to generate the output data Dout (image pickup signal) configured by the digital signal. Respective pieces of the output data Dout are output from the respective column selection sections 17 in order and transmitted to the outside (or input into a not illustrated internal memory) in this way.

In this regard, some of the radiation (the X-rays) incident upon the image pickup device 1 leaks into the pixel section 11A without being subjected to wavelength conversion. When the transistor 22 is exposed to the radiation so leaked into the pixel section 11A, such a malfunction as follows may occur. That is, since the transistor 22 has the silicon oxide film in the gate insulating film 121, when the radiation is incident upon this film that contains oxygen, electrons in the film are excited by so-called photoelectric effect, Compton scattering, electron pair creation, or the like. As a result, electron holes are trapped and accumulated in the gate insulating film 121 and the threshold voltage Vth of the transistor 22 is shifted to the negative side due to accumulation of the electron holes.

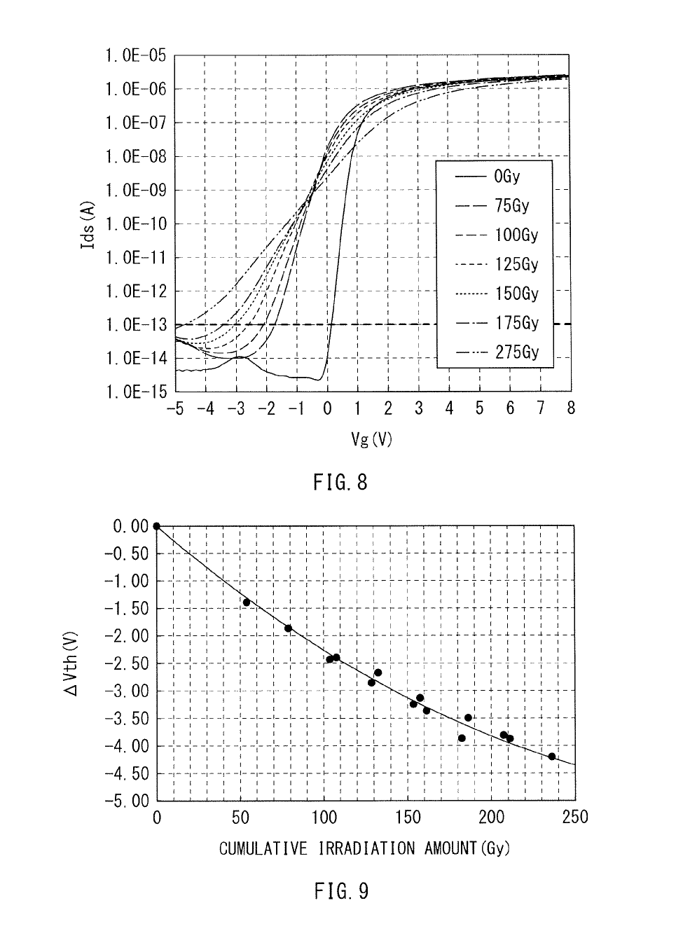

FIG. 8 illustrates one example of a relation of the current Ids with the voltage Vg (the current-voltage characteristic) when the transistor 22 made of low temperature polycrystalline silicon has been irradiated with X-rays. FIG. 9 illustrates one example of a relation between a cumulative irradiation amount (dose) (Gy) and a shift amount (AVth) of the threshold voltage to the negative side. As illustrated in FIG. 8, it is seen that when the transistor 22 has been irradiated with the X-rays, the threshold voltage Vth is gradually shifted to the negative side as the cumulative irradiation amount (dose) of the X-rays is increased from 0 Gy to 75 Gy, to 100 Gy, to 125 Gy, to 150 Gy, to 175 Gy, and then to 275 Gy. In addition, as the irradiation amount is increased, an S (sub-threshold swing) value gets worse accordingly. In addition, an increase in shift amount of the threshold voltage Vth induces a change in OFF current and ON current. It may become difficult to maintain the reliability of the transistor because, for example, the OFF current is increased to induce current leakage and/or the ON current is reduced to make signal read-out hardly possible or for other reasons. In the radiographic image pickup device that uses low-temperature polycrystalline silicon, in particular, the threshold voltage Vth of the transistor 22 is shifted to the negative side due to exposure to induce reliability degradation.

That is, since the pixel section 11A is more liable to be exposed to the radiation than the peripheral circuit section 11B, the threshold voltage Vth of the transistor 22 in the pixel section 11A is liable to be shifted to the negative side accordingly.

Therefore, the image pickup device 1 of the present embodiment is designed to make the threshold voltages of the transistors different from each other between the pixel section 11A and the peripheral circuit section 11B. Specifically, the threshold voltage Vth1 of the transistor TrA of the pixel section 11A is set to the value that is shifted from the value of the threshold voltage Vth0 of the transistor TrB of the peripheral circuit section 11B to the positive side. That is, even when threshold voltage shift occurs due to exposure of the pixel section 11A to the radiation, it becomes possible to mitigate an influence thereof (such as the above-mentioned increase in OFF current and reduction in ON current and so forth) by setting in advance the threshold voltage Vth1 of the transistor TrA in anticipation of such threshold voltage shifting as mentioned above. Describing in more detail, since threshold voltage shifting caused by exposure to the radiation occurs by accumulation of the electron holes in the silicon oxide film as described above, the initial (for example, when the cumulative irradiation amount reaches about 75Gy) shift amount reaches a relatively high value as illustrated in FIG. 8. Thereafter, the shift amount shows a tendency that it is gradually reduced regardless of an increase in the cumulative irradiation amount. Therefore, it is possible to increase the life of the transistor by setting the threshold voltage Vth1 to the positively shifted value in consideration of such an initial shift amount and so forth as mentioned above.

In the present embodiment, the threshold voltages of the transistors are made different from each other between the pixel section 11A that includes the plurality of pixels 20 each including the photoelectric conversion element 21 and the peripheral circuit section 11B of the pixel section 11A as described above. Thus, it is possible to set the threshold voltages of the respective transistors to appropriate values in anticipation of, for example, shifting of the threshold voltage of the transistor that would be more liable to occur in the pixel section 11A than in the peripheral circuit section 11B, and therefore it is possible to efficiently improve the life characteristics of the transistors. Accordingly, it is possible to achieve high reliability by mitigating an influence caused by shifting of the threshold voltage of the transistor.

In the following, modification examples (modification examples 1 to 5) of the above-mentioned embodiment will be described. It is to be noted that the same symbols are assigned to the same constitutional elements as those in the above-mentioned embodiment and description thereof is appropriately omitted.

### Modification Example 1

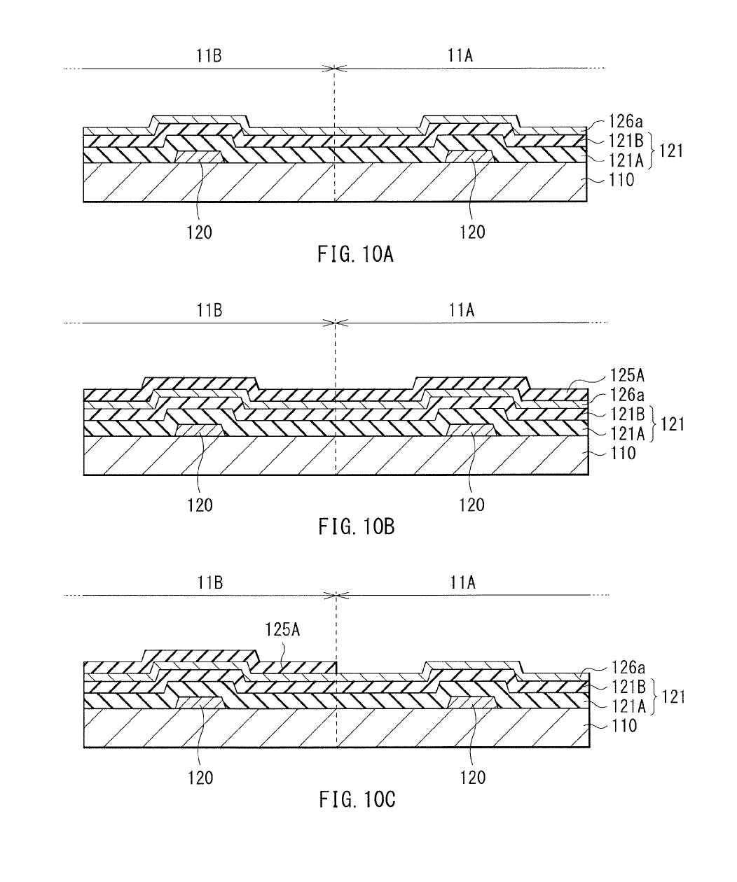

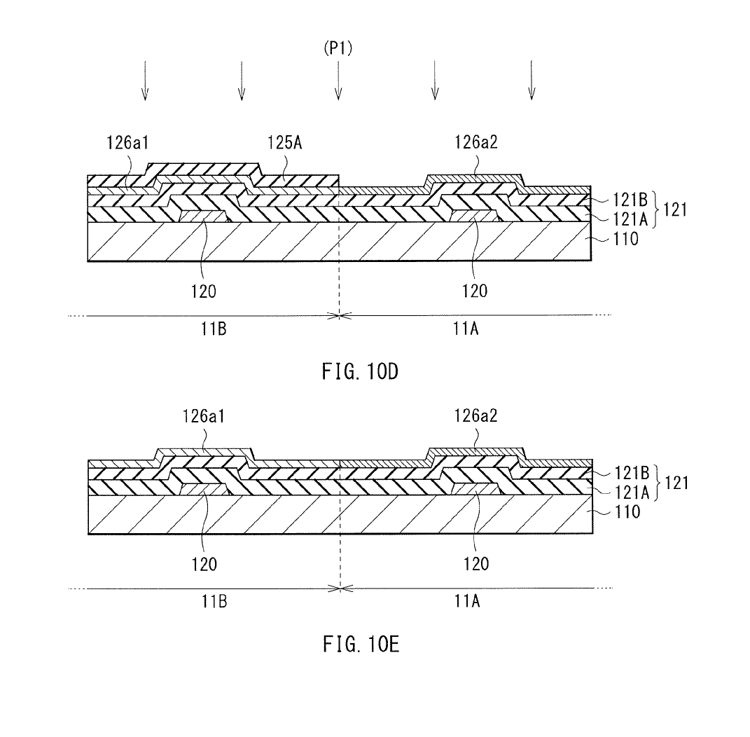

One method of setting the threshold voltages Vth0 and Vth1 by making the impurity concentrations of the respective semiconductor layers 126 (126a1 and 126a2) of the transistors TrA and TrB different from each other has been described in the above-mentioned embodiment. The method of making the impurity concentrations different from each other is not limited to the aforementioned method, and a stopper film may be used as in the present modification example. A method of setting the threshold voltages of the present modification example is illustrated in FIG. 10A to FIG. 10E in order of processes to be performed.

In the present modification example, first, the gate electrode 120, the gate insulating film 121 (the silicon nitride film 121A and the silicon oxide film 121B), and the semiconductor layer 126a are formed on the substrate 110 in this order as illustrated in FIG. 10A in the same way as in the above-mentioned embodiment.

Thereafter, a silicon oxide film 125A may be formed on the entire surface of the semiconductor layer 126a, for example, as a stopper film for ion implantation as illustrated in FIG. 10B. Then, the silicon oxide film 125A may be patterned by etching using, for example, a photolithographic method as illustrated in FIG. 10C. By this etching, part of the silicon oxide film 125A corresponding to the pixel section 11A is selectively removed and only the peripheral circuit section 11B is masked. It is to be noted that a thickness of the silicon oxide film 125A may be set to, for example, about 5 nm to about 20 nm both inclusive and preferably may be set to, for example, about 15 nm.

Then, impurity diffusion is performed by the ion implantation (P1) as illustrated in FIG. 10D. Since a peak position of an ion implantation profile is changed by performing the ion implantation with the peripheral circuit section 11B masked with the silicon oxide film 125A, it becomes possible to form the semiconductor layers 126a1 and 126a2 having the relation of the impurity concentrations as described above by performing the ion implantation process only one time.

Finally, the silicon oxide film 125A is removed as illustrated in FIG. 10E. It is also possible to set the threshold voltages Vth0 and Vth1 as described above in this way.

It is possible to reduce the number of the ion implantation processes to be performed in comparison with the above-mentioned embodiment by performing ion implantation by using, for example, the stopper film configured by the silicon oxide film 125A as in the present modification example. In addition, since the film thickness of the silicon oxide film 125A that is in contact with the semiconductor layer 126 (the semiconductor layer 126a2) is reduced in the pixel section 11A, it becomes possible to improve the resistivity against X-rays as described above.

It is to be noted that although the threshold voltage setting methods that have been described in the above-mentioned embodiment and modification example 1 are applicable to any of the bottom gate type, top gate type, and dual gate type transistors, it is possible to make the silicon oxide film 230A, for example, between later described second gate electrode 220B and semiconductor layer 226 thinner in the pixel section 11A than in the peripheral circuit section 11B, in particular, in case of the dual gate type transistors, which is advantageous for improving X-ray resistivity.

### Modification Example 2

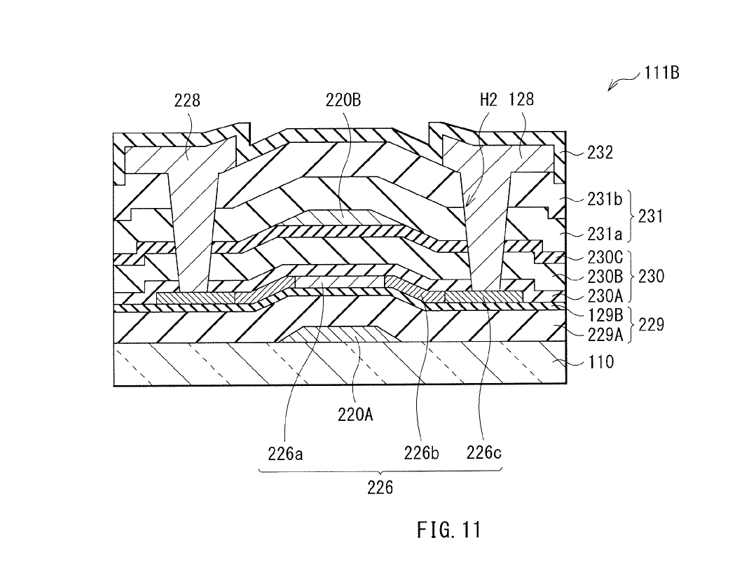

FIG. 11 illustrates one sectional configuration example of a field-effect transistor according to the modification example 2. Although in the above-mentioned embodiment, description has been made by giving the bottom gate type transistor as one example of the transistor 22, the transistor may be of the dual gate type as in the present modification example. In the following, a specific configuration example of the dual gate type transistor will be described.

The transistor 22 according to the present modification example may include a first gate electrode 220A and a first gate insulating film 229 formed so as to cover the first gate electrode 220A on the substrate 110, for example. The semiconductor layer 226 that includes a channel layer (an active layer) 226a, an LDD (Lightly Doped Drain) layer 226b, and an N⁺ layer 226c is formed on the first gate insulating film 229. A second gate insulating film 230 is formed so as to cover the semiconductor layer 226, and the second gate electrode 220B is disposed in a region that faces the first gate electrode 220A on the second gate insulating film 230. A first interlayer insulating film 231 having a contact hole H2 is formed on the second gate electrode 220B and a source-drain electrode 228 is formed so as to fill up the contact hole H2. A second interlayer insulating film 232 is formed on the first interlayer insulating film 231 and the source-drain electrode 228.

The semiconductor layer 226 is made of the same material as the semiconductor layer 126 in the above-mentioned embodiment. In the semiconductor layer 226, the LDD layer 226b is formed between the channel layer 226a and the N+ layer 226c in order to reduce leak currents. The function and constituent material of the source-drain electrode 228 are the same as those of the source-drain electrode 128 in the above-mentioned embodiment.

The first gate electrode 220A and the second gate electrode 220B are each made of the same material as the gate electrode 120 in the above-mentioned embodiment. The first gate electrode 220A and the second gate electrode 220B are disposed so as to face each other with the first gate insulating film 229, the semiconductor layer 226, and the second gate insulating film 230 interposed in between as described above.

Each of the first gate insulating film 229 and the second gate insulating film 230 may be a single layer film configured by any one of, for example, a silicon oxide film, a silicon nitride film, a silicon oxynitride film, and so forth, or may be a laminated film configured by two or more of the above-mentioned films, in the same way as the gate insulating film 121 in the above-mentioned embodiment. The first gate insulating film 229 may be configured by laminating a silicon nitride film 229A and a silicon oxide film 229B in order from the substrate 110 side, for example. The second gate insulating film 230 may be configured by laminating a silicon oxide film 230A, a silicon nitride film 230B, and a silicon oxide film 230C in order from the substrate 110 side, for example. However, when the semiconductor layer 226 is made of low-temperature polycrystalline silicon, it may be desirable to provide the silicon oxide films (the silicon oxide films 229B and 230A) on surfaces that are in contact with the semiconductor layer 226 (describing in detail, the channel layer 226a) in the first gate insulting film 229 and the second gate insulating film 230 from the viewpoint of manufacturability.

Each of the first interlayer insulating film 231 and the second interlayer insulating film 232 may be a single layer film configured by any one of, for example, a silicon oxide film, a silicon nitride film, a silicon oxynitride film, and so forth, or may be a laminated film configured by two or more of the above-mentioned films. For example, the first interlayer insulating film 231 may be configured by laminating a silicon oxide film 231a and a silicon nitride film 231b in order from the substrate 110 side and the second interlayer insulating film 232 may be configured by a silicon oxide film.

### Modification Example 3

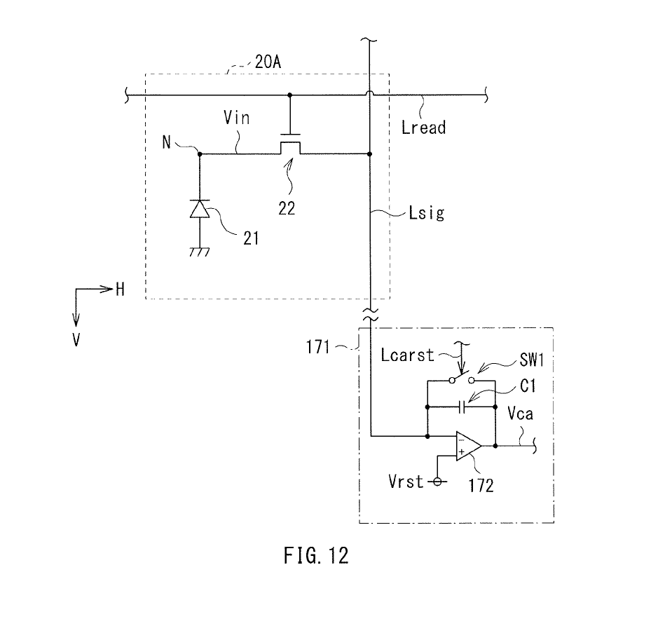

FIG. 12 illustrates one circuit configuration example of a pixel (a pixel 20A) according to the modification example 3 together with one circuit configuration example of the charge amplifier circuit 171 described in the above-mentioned embodiment. The pixel 20A of the present modification example has the so-called passive type circuit configuration similarly to the pixel 20 of the embodiment, and includes one photoelectric conversion element 21 and one transistor 22. In addition, the read-out control line Lread that extends along the H direction and the signal line Lsig that extends along the V direction are connected to the pixel 20A.

However, in the pixel 20A of the present modification example, the anode of the photoelectric conversion element 21 is connected to the accumulation node N and the cathode thereof is connected to the ground (the earth) unlike the pixel 20 of the above-mentioned embodiment. In the pixel 20A, the accumulation node N may be connected to the anode of the photoelectric conversion element 21 as described above, and it is possible to obtain the same effects as those by the image pickup device 1 according to the above-mentioned embodiment also when configuring the pixel in this way.

### Modification Examples 4-1 and 4-2

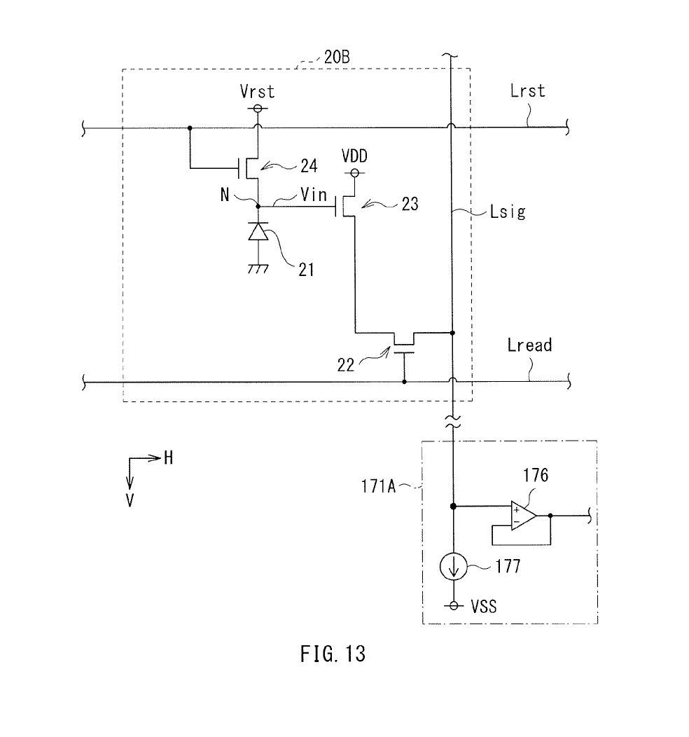

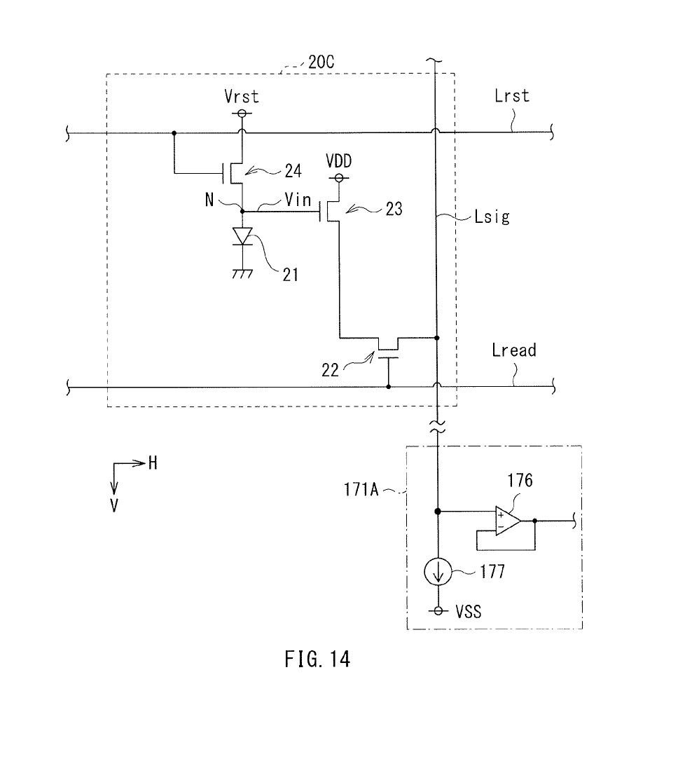

FIG. 13 illustrates one circuit configuration example of a pixel (a pixel 20B) according to the modification example 4-1 together with one circuit configuration example of a charge amplifier 171A that will be described later. In addition, FIG. 14 illustrates one circuit configuration example of a pixel (a pixel 20C) according to the modification example 4-2 together with the circuit configuration example of the charge amplifier circuit 171A. The pixels 20B and 20C according to the respective modification examples 4-1 and 4-2 each include a so-called active type pixel circuit unlike the pixels 20 and 20A described so far.

Each of the active type pixels 20B and 20C includes one photoelectric conversion element 21, and three transistors 22, 23, and 24. The read-out control line Lread and a reset control line Lrst that extend along the H direction and the signal line Lsig that extends in the V direction are connected to the pixels 20B or 20C.

In each of the pixels 20B and 20C, a gate of the transistor 22 is connected to the read-out control line Lread, a source thereof is connected to the signal line Lsig, and a drain thereof is connected to a drain of the transistor 23 that configures a source follower circuit. A source of the transistor 23 is connected to a power source VDD, and a gate thereof is connected to the cathode (the example in FIG. 13) or the anode (the example in FIG. 14) of the photoelectric conversion element 21 and to a drain of the transistor 24 that functions as a transistor for reset via the accumulation node N. A gate of the transistor 24 is connected to the reset control line Lrst and a reset voltage Vrst is applied to a source thereof. In the modification example 4-1, the anode of the photoelectric conversion element 21 is connected to the ground, while in the modification example 4-2, the cathode of the photoelectric conversion element 21 is connected to the ground.

In addition, the charge amplifier circuit 171A in each of the modification examples 4-1 and 4-2 includes an amplifier 176 and a constant current source 177, in place of the charge amplifier 172, the capacitor C1, and the switch SW1 in the aforementioned charge amplifier circuit 171. In the amplifier 176, the signal line Lsig is connected to a positive-side input terminal and a negative-side input terminal and an output terminal are connected to each other to form a voltage follower circuit. It is to be noted that one terminal of the constant current source 177 is connected to one end side of the signal line Lsig and a power source VSS is connected to the other terminal of the constant current source 177.

### Modification Examples 5-1 and 5-2

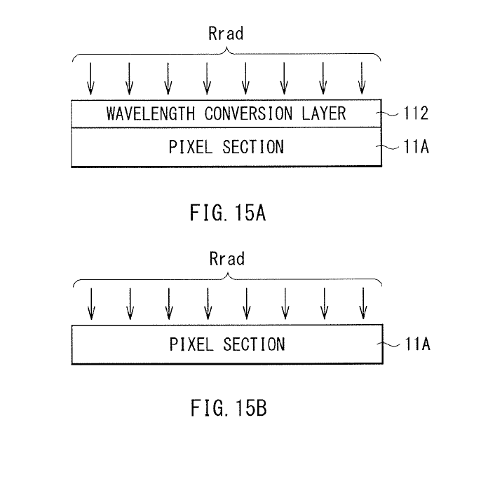

FIG. 15A and FIG. 15B schematically illustrate schematic configuration examples of the pixel section 11A according to the modification examples 5-1 and 5-2 respectively. When the image pickup device 1 of the above-mentioned embodiment is a radiographic image pickup device, the pixel section 11A has a configuration of any one of the modification examples 5-1 and 5-2.

The pixel section 11A according to the modification example 5-1 illustrated in FIG. 15A may be applied to the so-called indirect conversion type radiographic image pickup device, and includes a wavelength conversion layer 112 on the pixel section 11A (a light receiving face side). The wavelength conversion layer 112 is adapted to convert radiation Rrad (such as α rays, β rays, γrays, X rays and so forth) into light of a wavelength in a sensitivity range of the photoelectric conversion element 21 of the pixel section 11A, making it possible to read out information based on the radiation Rrad in the pixel section 11A owing to provision of the wavelength conversion layer 112. The wavelength conversion layer 112 may be configured by, for example, a phosphor (for example, a scintillator) that converts the radiation such as the X rays and so forth into visible light. The wavelength conversion layer 112 may be formed by laminating, for example, an organic flattening film or a flattening film made of a spin-on glass material and so forth and a phosphor film. The phosphor film may be made of, for example, CsI (added with Tl), Gd₂O₂S, BaFX (X may be Cl, Br, I, and so forth), NaI, and/or CaF₂ and so forth.

The pixel section 11A according to the modification example 5-2 illustrated in FIG. 15B may be applied to the so-called direct conversion type radiographic image pickup device, and in this case, the pixel section 11A has a function of absorbing the incident radiation Rrad and converting the thus-absorbed incident radiation Rrad into an electric signal. The pixel section 11A of the present modification example may be configured by, for example, an amorphous selenium (a-Se) semiconductor, a cadmium telluride (CdTe) semiconductor and so forth. It is to be noted that a circuit configuration of the pixel 20 in case of the direct conversion type image pickup device is equivalent to a configuration in which the photoelectric conversion element 21 is replaced with a capacitor in the respective elements illustrated in FIG. 2.

The indirect conversion type or direct conversion type radiographic image pickup device as mentioned above is utilized as various types of image pickup devices that acquire the electric signal on the basis of the radiation Rrad. This image pickup device may be applicable to, for example, a medical X-ray image pickup device (a digital radiography and so forth), a baggage-screening X-ray image pickup device used in an airport and so forth, an industrial X-ray image pickup device (for example, a device for examining dangerous goods and so forth in a container) and so forth.

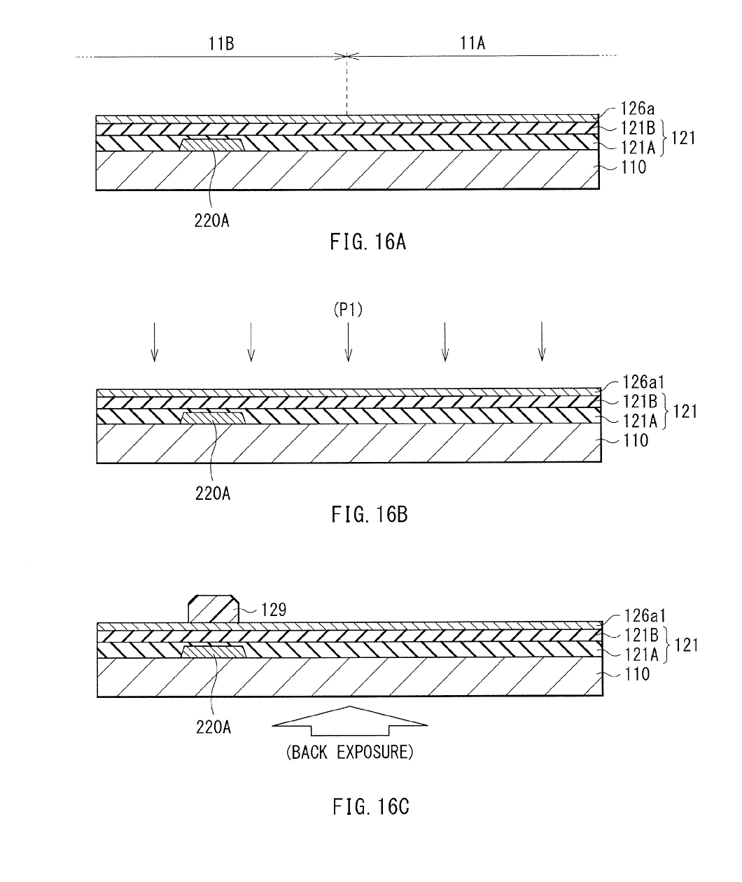

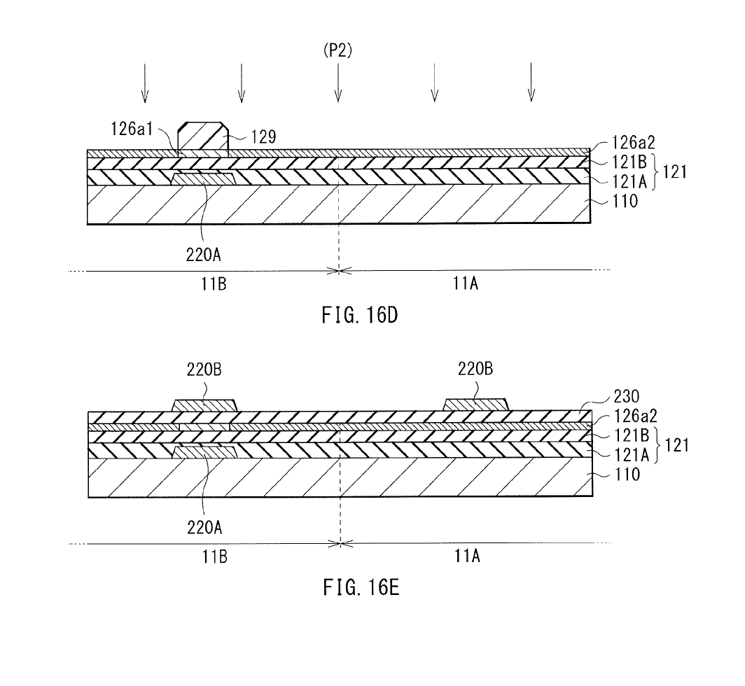

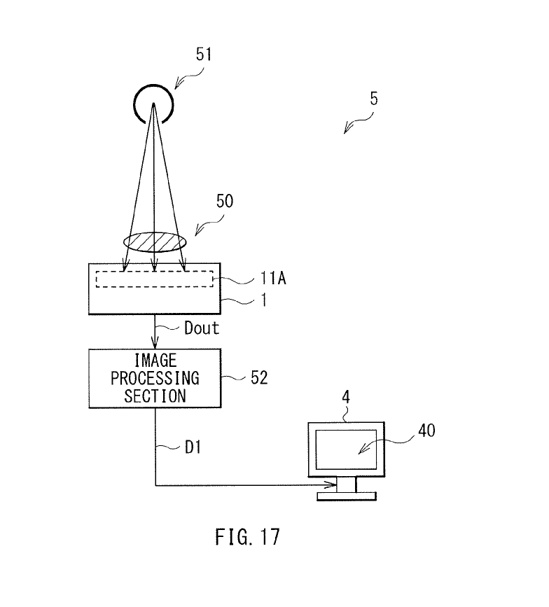

It is to be noted that although in the above-mentioned embodiment and modification examples, the bottom gate type or dual gate type structure has been illustrated as the structure example of the transistor 22, the structure may be of the top gate type. In addition, it is possible to reduce the number of masks by arranging the top gate type transistor in the pixel section 11A and arranging the dual gate type transistor in the peripheral circuit section 11B for reasons as follows. That is, after the first gate electrode 220A is formed only in the peripheral circuit section 11B, the first gate insulating film 121 and the semiconductor layer 126a are formed on the substrate 110 as illustrated in FIG. 16A. Thereafter, impurity diffusion is performed by the first ion implantation (P1) to form the semiconductor layer 126a1 having the predetermined impurity concentration over the whole regions of the pixel section 11A and the peripheral circuit section 11B as illustrated in FIG. 16B. Then, a photoresist film 129 is formed only in a region that faces the first gate electrode 220A in the peripheral circuit section 11B as illustrated in FIG. 16C. Thereafter, the second ion implantation (P2) is performed as illustrated in FIG. 16D. Thus, the impurities are doped into a region other than the region that faces the first gate electrode 220A in the semiconductor layer 126a1, and it becomes possible to form the semiconductor layer 126a2 that is higher in impurity concentration than the semiconductor layer 126a1 in the pixel section 11A as illustrated in FIG. 16E. The dual gate type transistor may be arranged in the peripheral circuit section 11B in this way, and in this case it is possible to reduce the number of the masks for implantation.

### Application Example

The image pickup devices according to the above-mentioned embodiment and modification examples (the modification examples 1 to 5) are also applicable to such an image pickup display system as described hereinafter.

FIG. 17 schematically illustrates one schematic configuration example of an image pickup display system (an image pickup display system 5) according to an application example. The image pickup display system 5 includes the image pickup device 1 that includes the pixel section 11A and so forth according to any of the above-mentioned embodiment and modification examples, an image processing section 52, and a display 4. In this example, the image pickup display system 5 is configured as an image pickup display system using radiation (a radiographic image pickup display system).

The image processing section 52 is adapted to generate image data D1 by performing predetermined image processing on the output data (the image pickup signal) output from the image pickup device 1. The display 4 is adapted to perform image display based on the image data D1 generated by the image processing section 52 on a predetermined monitor screen 40.

In this image pickup display system 5, the image pickup device 1 (here, the radiographic image pickup device) acquires the image data (the output data) Dout of an object 50 on the basis of irradiation light (here, the radiation) radiated from a light source (here, a radiation source such as an X-ray source and so forth) 51 toward the object 50 and outputs the data so acquired to the image processing section 52. The image processing section 52 performs the above-mentioned predetermined image processing on the input image data Dout and outputs the image data (the display data) D1 so subjected to the image processing to the display 4. The display 4 displays image information (a picked-up image) on the monitor screen 40 on the basis of the input image data D1.

Since, in the image pickup display system of the present application example, it is possible to acquire the image of the object 50 as the electric signal by the image pickup device 1 as described above, it becomes possible to display the image by transmitting the acquired electric signal to the display 4. That is, it becomes possible to observe the image of the object without using such a radiographic film as has ever been used, and it becomes possible to cope with moving image capturing and moving image display.

It is to be noted that although in the present application, description has been made by giving an example that the image pickup device 1 is configured as the radiographic image pickup device and the image pickup display system is configured as the system using the radiation accordingly, the image pickup display system according to one embodiment of the present disclosure is also applicable to a system using an image pickup device of another system.

Although the example embodiment, the modification examples, and the application example of the present disclosure have been described above, the contents of the present disclosure are not limited to the above-mentioned embodiment, modification examples, and application example, and such example embodiment and so forth may be modified in a variety of ways. For example, the circuit configuration of the pixel in the pixel section in any of the above-mentioned embodiment, modification examples, and application example may be another circuit configuration, not limited to the circuit configurations (the circuit configurations of the pixels 20, and 20A to 20C) described in the above-mentioned embodiment, modification examples and application example. Likewise, the circuit configurations of the row scanning section, the column selection section and so forth may be other circuit configurations, not limited to those described in the above-mentioned embodiment, modification examples, and application example.

In addition, the pixel section, the row scanning section, the A/D conversion section (the column selection section), and the column scanning section and so forth described in the above-mentioned embodiment, modification examples and application example may be formed on, for example, the same substrate. Specifically, it becomes also possible to form the switches and so forth in the above-mentioned circuit sections on the same substrate, for example, by using a polycrystalline semiconductor such as low-temperature polycrystalline silicon and so forth. Therefore, it is possible to perform driving operations on the same substrate on the basis of a control signal from, for example, an external system control section, and to achieve improvement in reliability when slimming down the bezel (a three-side-free bezel structure) and connecting wiring.

Furthermore, the technology encompasses any possible combination of some or all of the various embodiments described herein and incorporated herein.

It is possible to achieve at least the following configurations from the above-described example embodiments of the disclosure.

(1) An image pickup device, including:

a pixel section including a plurality of pixels, each of the pixels being configured to generate a signal charge based on radiation;

a first field-effect transistor provided in the pixel section; and

a second field-effect transistor provided in a peripheral circuit section of the pixel section,

wherein the first transistor has a threshold voltage and the second transistor has a threshold voltage that are different from each other.

(2) The image pickup device according to (1), wherein the threshold voltage of the first transistor has a value that is shifted to one of a positive side and a negative side from a value of the threshold voltage of the second transistor as a reference.
(3) The image pickup device according to (2), wherein the threshold voltage of the first transistor is set to the value that is more shifted to the positive side than the value of the threshold voltage of the second transistor.
(4) The image pickup device according to any one of (1) to (3), wherein

the first transistor includes a first semiconductor layer that forms a channel,

the second transistor includes a second semiconductor layer that forms a channel, and

the first semiconductor layer has an impurity concentration and the second semiconductor layer has an impurity concentration that are different from each other.

(5) The image pickup device according to (4), wherein the impurity concentration of the first semiconductor layer is higher than the impurity concentration of the second semiconductor layer.
(6) The image pickup device according to any one of (1) to (5), wherein

the first transistor has a double-sided gate type element structure, and

the second transistor has one of a bottom gate type element structure and a top gate type element structure.

(7) The image pickup device according to any one of (1) to (6), wherein each of the first transistor and the second transistor includes a gate insulating film that includes a silicon oxide film.
(8) The image pickup device according to any one of (4) to (7), wherein each of the first semiconductor layer and the second semiconductor layer includes one of polycrystalline silicon, microcrystalline silicon, amorphous silicon, and an oxide semiconductor.
(9) The image pickup device according to (8), wherein each of the first semiconductor layer and the second semiconductor layer includes low-temperature polycrystalline silicon.
(10) The image pickup device according to any one of (1) to (9), wherein the image pickup device is an indirect conversion type radiographic image pickup device.
(11) The image pickup device according to any one of (1) to (9), wherein the image pickup device is a direct conversion type radiographic image pickup device.
(12) The image pickup device according to any one of (1) to (11), wherein the radiation includes X-ray.
(13) The image pickup device according to any one of (1) to (10) and (12), wherein each of the pixels includes a photoelectric conversion element that is one of a PIN-type photodiode and an MIS-type sensor.
(14) An image pickup display system provided with an image pickup device and a display configured to perform image display based on an image pickup signal obtained by the image pickup device, the image pickup device including:

a pixel section including a plurality of pixels, each of the pixels being configured to generate a signal charge based on radiation;

a first field-effect transistor provided in the pixel section; and

a second field-effect transistor provided in a peripheral circuit section of the pixel section,

wherein the first transistor has a threshold voltage and the second transistor has a threshold voltage that are different from each other.

It should be understood by those skilled in the art that various modifications, combinations, sub-combinations and alterations may occur depending on design requirements and other factors insofar as they are within the scope of the appended claims or the equivalents thereof.

What is claimed is:

1. An image pickup device, comprising:
a pixel section including a plurality of pixels, each of the pixels being configured to generate a signal charge based on radiation;
a first field-effect transistor provided in the pixel section; and
a second field-effect transistor provided in a peripheral circuit section of the pixel section,
wherein,
the first transistor has a threshold voltage and the second transistor has a threshold voltage that are different from each other.

2. The image pickup device according to claim 1, wherein the threshold voltage of the first transistor has a value that is shifted to one of a positive side and a negative side from a value of the threshold voltage of the second transistor as a reference.

3. The image pickup device according to claim 2, wherein the threshold voltage of the first transistor is set to the value that is more shifted to the positive side than the value of the threshold voltage of the second transistor.

4. The image pickup device according to claim 1, wherein:
the first transistor includes a first semiconductor layer that forms a channel,
the second transistor includes a second semiconductor layer that forms a channel, and
the first semiconductor layer has an impurity concentration and the second semiconductor layer has an impurity concentration that are different from each other.

5. The image pickup device according to claim 4, wherein the impurity concentration of the first semiconductor layer is higher than the impurity concentration of the second semiconductor layer.

6. The image pickup device according to claim 1, wherein:
the first transistor has a double-sided gate type element structure, and
the second transistor has one of a bottom gate type element structure and a top gate type element structure.

7. The image pickup device according to claim 1, wherein each of the first transistor and the second transistor includes a gate insulating film that includes a silicon oxide film.

8. The image pickup device according to claim 4, wherein each of the first semiconductor layer and the second semiconductor layer includes one of polycrystalline silicon, microcrystalline silicon, amorphous silicon, and an oxide semiconductor.

9. The image pickup device according to claim 8, wherein each of the first semiconductor layer and the second semiconductor layer includes low-temperature polycrystalline silicon.

10. The image pickup device according to claim 1, wherein the image pickup device is an indirect conversion type radiographic image pickup device.

11. The image pickup device according to claim 1, wherein the image pickup device is a direct conversion type radiographic image pickup device.

12. The image pickup device according to claim 1, wherein the radiation includes X-ray.

13. The image pickup device according to claim 1, wherein each of the pixels includes a photoelectric conversion element that is one of a PIN-type photodiode and an MIS-type sensor.

14. An image pickup display system comprising:
an image pickup device; and
a display configured to perform image display based on an image pickup signal obtained from the image pickup device,
wherein the image pickup device comprises
(a) a pixel section including a plurality of pixels, each of the pixels configured to generate a signal charge based on radiation,
(b) a first field-effect transistor in the pixel section, and
(c) a second field-effect transistor in a peripheral circuit section of the pixel section, the first transistor and the second transistor have respective threshold voltages that are different from each other.
